(19) United States
(12) Patent Application Publication
(10) Pub. No.: US 2016/0366764 A1
(43) Pub. Date: Dec. 15, 2016

(54) CIRCUIT BOARD

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventor: BO PENG, Wuhan (CN)

(21) Appl. No.: 14/750,656

(22) Filed: Jun. 25, 2015

(30) Foreign Application Priority Data
Jun. 9, 2015 (CN) 201510310802.7

(51) Int. Cl. H05K 1/18

(52) U.S. Cl. CPC H05K 1/18; H05K 2201/09818; H05K 2201/10015

(57) ABSTRACT

A circuit board includes a circuit board body, a first capacitor, and a second capacitor. The circuit board body includes a first side portion and a second side portion. The first capacitor and the second capacitor are surrounded by an electronic field. The first capacitor is mounted in the first side portion. The second capacitor is mounted in the second side portion. The first capacitor is configured to generate a first force. The first force is configured to be exerted on the first side portion. The first force is in a first direction. The second capacitor is configured to generate a second force when the first capacitor generates the first force. The second force is configured to be exerted on the second side portion. The second force is in a second direction. The first direction is opposite to the second direction.

### FIELD

The subject matter herein generally relates to circuit boards.

### BACKGROUND

A multi-layer ceramic capacitors (MLCC) is mounted in a circuit board and is surrounded by an electronic field, the MLCC may be elastically deformed by the electronic field when operating which will makes the MLCC strike the circuit board and generate noise.

### BRIEF DESCRIPTION OF THE DRAWINGS

Implementations of the present technology will now be described, by way of example only, with reference to the attached figures.

FIG. 1 is a block diagram of one embodiment of a circuit board.

FIG. 2 is a diagram view of the circuit board of FIG. 1.

FIG. 3 is similar to FIG. 1, but viewed in a different aspect.

FIG. 4 is a side view of the circuit board of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series, and the like.

The present disclosure is described in relation to a circuit board which prevents noise.

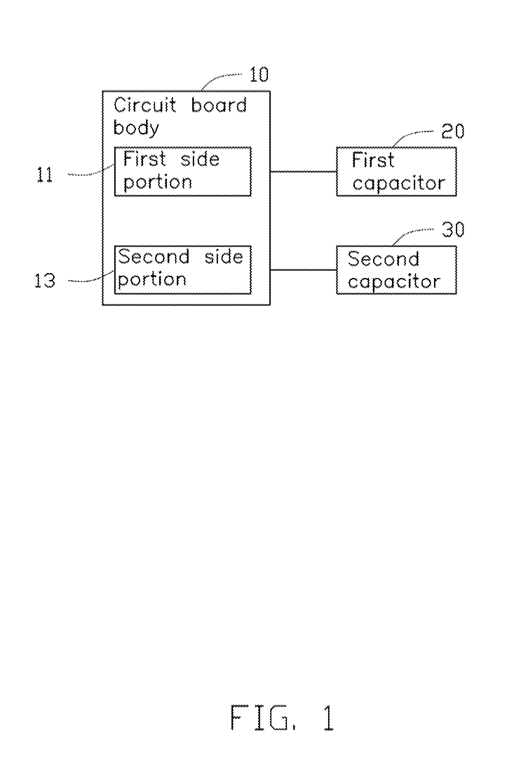

FIG. 1 illustrates an embodiment of a circuit board. The circuit board comprises a circuit board body 10, a first capacitor 20, and a second capacitor 30. The circuit board body 10 comprises a first side portion 11 and a second side portion 13. The first capacitor 20 is mounted in the first side portion 11. The second capacitor 30 is mounted in the second side portion 13.

In at least one embodiment, each of the first capacitor 20 and the second capacitor 30 is a multi-layer ceramic capacitors (MLCC) and is ferroelectric.

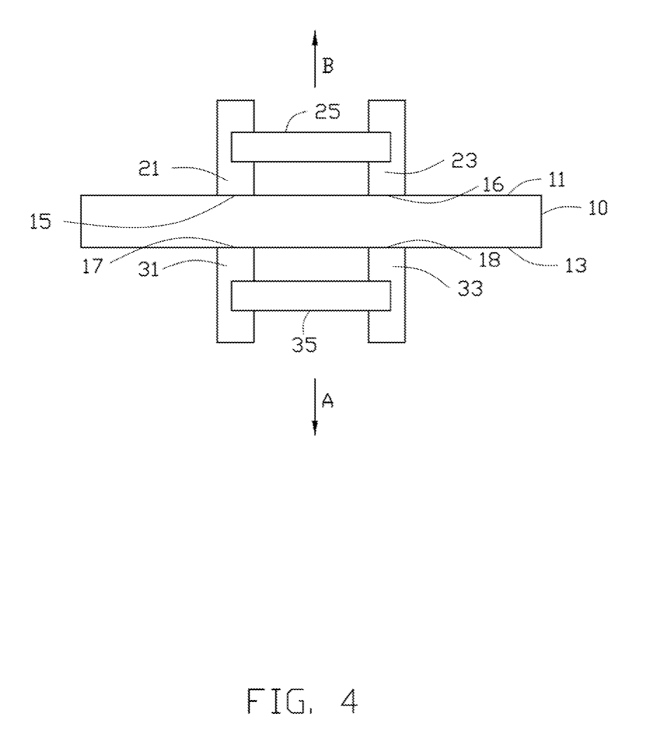

FIG. 4 illustrates that the first side portion 11 and the second side portion 13 are located at two opposite sides of the circuit board body 10. The first side portion 11 is parallel to the second side portion 13. The first side portion 11 comprises a first mounting portion 15 and a second mounting portion 16. The second side portion 13 comprises a third mounting portion 17 corresponding to the first mounting portion 15 and a fourth mounting portion 18 corresponding to the second mounting portion 16.

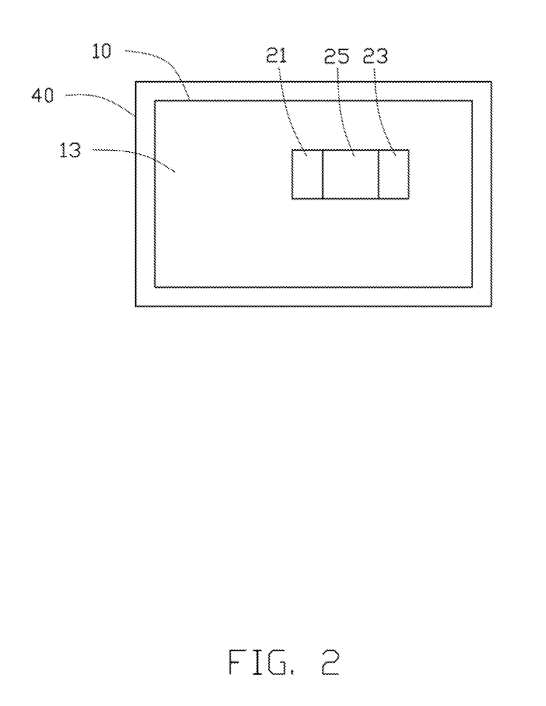

FIG. 2 illustrates that the first capacitor 20 comprises a first terminal portion 21, a second terminal portion 23, and a first main body 25. The first terminal portion 21 and the second terminal portion 23 are located at two ends of the first capacitor 20. The first main body 25 is located between the first terminal portion 21 and the second terminal portion 23.

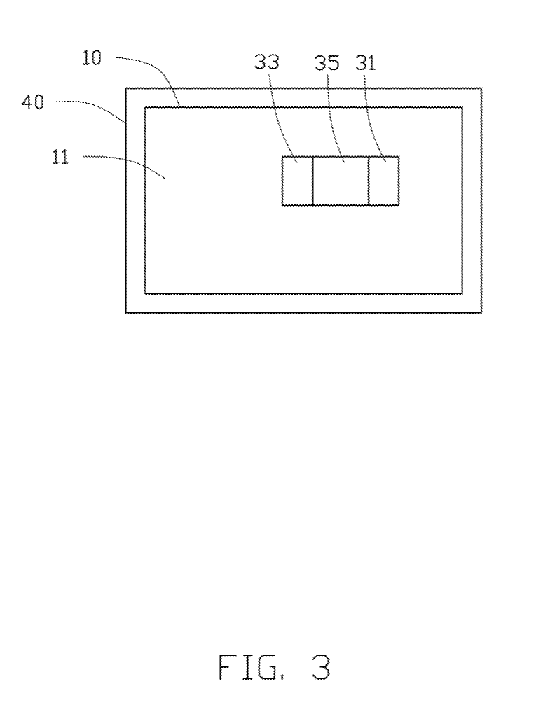

FIG. 3 illustrates that the second capacitor 30 comprises a third terminal portion 31, a fourth terminal portion 33, and a second main body 35. The third terminal portion 31 and the fourth terminal portion 33 are located at two ends of the second capacitor 30. The second main body 35 is located between the third terminal portion 31 and the fourth terminal portion 33.

When in assembly, the circuit board body 10 is placed on a desk (not shown) parallel to a plane 40. The first terminal portion 21 is mounted in the first mounting portion 15. The second terminal portion 23 is mounted in the second mounting portion 16. The third terminal portion 31 is mounted in the third mounting portion 17. The fourth terminal portion 33 is mounted in the fourth mounting portion 18. The first side portion 11 and the second side portion 13 are parallel to the plane 40.

In at least one embodiment, the first terminal portion 21 is an anode terminal portion, the second terminal portion 23 is a cathode terminal portion, the third terminal portion 31 is an anode terminal portion, and the fourth terminal portion 33 is a cathode terminal portion. In the other embodiment, the first terminal portion 21 is a cathode terminal portion, the second terminal portion 23 is an anode terminal portion, the third terminal portion 31 is a cathode terminal portion, and the fourth terminal portion 33 is an anode terminal portion.

The circuit board body 10 is surrounded by an electronic field. The first capacitor 20 and the second capacitor 30 are also surrounded by the electronic field. The first capacitor 20 alternately generates a first force and a second force to strike the circuit board body 10. The second capacitor 30 alternately generates a third force and a fourth force to strike the circuit board body 10. The first force and the fourth force are in a first direction A. The second force and the third are in a second direction B. The first direction A and the second direction B are perpendicular to the plane 40. The first direction A is opposite to the second direction B. The first force is equal to the second force, the third force, and the fourth force. When the first force is exerted on the circuit board body 10, the third force is exerted on the circuit board body 10. The first force and the third force are equilibrants. The first force and the third force are exerted on the circuit board body 10, thus avoiding noise. When the second force is exerted on the circuit board body 10, the fourth force is exerted on the circuit board body 10. The second force and the fourth force are equilibrants. The second force and the fourth force are exerted on the circuit board body 10, thus preventing noise.

In at least one embodiment, when the first capacitor 20 and the second capacitor 30 are charged, a current flows to the second terminal portion 23 from the first terminal portion 21, the current flows to the fourth terminal portion 33 from the third terminal portion 31. The first capacitor 20 alternately generates a first force in the first direction A and a second force in the second direction B to strike the circuit board body 10. The second capacitor 30 alternately generates a third force in the second direction B and a fourth force in the first direction A to strike the circuit board body 10. When the first capacitor 20 and the second capacitor 30 are discharged, a first current via the first capacitor 20 flows to the first terminal portion 21 from the second terminal portion 23. A second current via the second capacitor 30 flows to the third terminal portion 31 from the fourth terminal portion 33. The first capacitor 20 alternately generates a first force in the second direction B and a second force in the first direction A to the circuit board body 10. The second capacitor 30 alternately generates a third force in the first direction A and a fourth force in the second direction B to strike the circuit board body 10. When the first force is exerted on the circuit board body 10, the third force is exerted on the circuit board body 10. When the first the second force is exerted on the circuit board body 10, the fourth force is exerted on the circuit board body 10. The first force and the third force are equilibrants. The first force and the third force are exerted on the circuit board body 10, thus avoiding noise when the force from the first capacitor 20 and the second capacitor 30 strike the circuit board body 10. The second force and the fourth force are equilibrants. The second force and the fourth force are exerted on the circuit board body 10, thus avoiding noise when the force from the first capacitor 20 and the second capacitor 30 strike the circuit board body 10.

It is to be understood that even though numerous characteristics and advantages have been set forth in the foregoing description of embodiments, together with details of the structures and functions of the embodiments, the disclosure is illustrative only and changes may be made in detail, including in the matters of shape, size, and arrangement of parts within the principles of the disclosure to the full extent indicated by the broad general meaning of the terms in which the appended claims are expressed.

1. A circuit board comprising:
a circuit board body having:
a first side portion, and
a second side portion;
a first capacitor mounted in the first side portion; and
a second capacitor mounted in the second side portion;
wherein the first capacitor and the second capacitor are coupled by an electronic field;
wherein the first capacitor is configured to generate a first force exerted on the first side portion in a first direction;
wherein the second capacitor is configured to generate a second force exerted on the second side portion in a second direction when the first force is exerted on the first side portion; and
wherein the first direction is opposite to the second direction.

2. The circuit board of claim 1, wherein the first force is equal to the second force.

3. The circuit board of claim 1, wherein the first capacitor is ferroelectric.

4. The circuit board of claim 1, wherein the first side portion and the second side portion are located at two opposite sides of the circuit board body.

5. The circuit board of claim 4, wherein the first side portion is parallel to the second side portion.

6. The circuit board of claim 1, wherein the first capacitor comprises a first terminal portion and a second terminal portion, the first terminal portion and the second terminal portion are located at two opposite sides of the first capacitor, the first side portion comprises a first mounting portion and a second mounting portion, the first terminal portion is mounted in the first mounting portion, and the second terminal portion is mounted in the second mounting portion.

7. The circuit board of claim 6, wherein the second capacitor comprises a third terminal portion and a fourth terminal portion, the second side portion comprises a third mounting portion corresponding to the first mounting portion and a fourth mounting portion corresponding to the second mounting portion.

8. The circuit board of claim 7, wherein when the first capacitor and the second capacitor are charged, a first current flows to the second terminal portion from the first terminal portion, and a second flows to the fourth terminal portion from the third terminal portion.

9. The circuit board of claim 1, wherein the first direction is perpendicular to the first side portion.

10. The circuit board of claim 9, wherein the first capacitor is further configured to generate a third force in the electronic field, the third force is configured to be exerted on the first side portion in the second direction, the second capacitor is further configured to generate a fourth force, and the fourth force is configured to be exerted on exerted on the second side portion in the first direction when the third force is exerted on the first side portion.

11. A circuit board comprising:
a circuit board body having:
a first side portion; and
a second side portion;
a first capacitor mounted in the first side portion; and
a second capacitor mounted in the second side portion;
wherein the first capacitor and the second capacitor are coupled by an electronic field;
wherein the first capacitor is configured to alternatively generate a first force and a second force;
wherein the first force and the second force are configured to be alternatively exerted on the first side portion;
wherein the first force is in a first direction;
wherein the second force is in a second direction;
wherein the second capacitor is configured to alternatively generate a third force and a fourth force;
wherein the third force is configured to be exerted on the second side portion in the second direction when the first force is exerted on the first side portion;
wherein the fourth force is configured to be exerted on the second side portion in the first direction when the second force is exerted on the first side portion; and
wherein the first direction is opposite to the second direction.

12. The circuit board of claim 11, wherein the first force is equal to the third force.

13. The circuit board of claim 11, wherein the second force is equal to the fourth force.

14. The circuit board of claim 11, wherein each of the first capacitor and the second capacitor is ferroelectric.

15. The circuit board of claim 11, wherein the first side portion and the second side portion are located at two opposite sides of the circuit board body.

16. The circuit board of claim 15, wherein the first side portion is parallel to the second side portion.

17. The circuit board of claim 11, wherein the first capacitor comprises a first terminal portion and a second terminal portion, the first terminal portion and the second terminal portion are located at two opposite sides of the first capacitor, the first side portion comprises a first mounting portion and a second mounting portion, the first terminal portion is mounted in the first mounting portion, and the second terminal portion is mounted in the second mounting portion.

18. The circuit board of claim 17 wherein the second capacitor comprises a third terminal portion and a fourth terminal portion, the second side portion comprises a third mounting portion corresponding to the first mounting portion and a fourth mounting portion corresponding to the second mounting portion.

19. The circuit board of claim 18, wherein when the first capacitor and the second capacitor are charged, a first current flows to the second terminal portion from the first terminal portion, and a second flows to the fourth terminal portion from the third terminal portion.

20. The circuit board of claim 11, wherein the first direction is perpendicular to the first side portion.
